(19) United States
(12) Patent Application Publication
(10) Pub. No.: US 2013/0127489 A1
(43) Pub. Date: May 23, 2013

(54) ELECTRONIC LOAD FOR TESTING DIMM SLOT

(71) Applicants: YUN BAI, Shenzhen City (CN); FU-SEN YANG, Shenzhen City (CN); SONG-LIN TONG, Shenzhen City (CN)

(72) Inventors: YUN BAI, Shenzhen City (CN); FU-SEN YANG, Shenzhen City (CN); SONG-LIN TONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., ShenZhen City (CN)

(21) Appl. No.: 13/589,166

(22) Filed: Aug. 19, 2012

(30) Foreign Application Priority Data
Nov. 23, 2011 (CN) 201110375949.6

(51) Int. Cl. G01R 31/30

(52) U.S. Cl. 324/763.01

(57) ABSTRACT

An exemplary electronic load includes a simulation load, a comparison circuit, a sample resistor, and a voltage control circuit. The comparison circuit includes a comparator. The sample resistor samples current flowing through the simulation load, and outputs the sampled current to a negative input of the comparator. An output of the comparator is connected to the simulation load. The voltage control circuit outputs an adjustable control voltage to a positive input of the comparator to control the simulation load to output an adjustable current.

### BACKGROUND

1. Technical Field

The disclosure generally relates to dual inline memory modules (DIMM) slot testing devices, and particularly to an electronic load for testing DIMM slots.

2. Description of the Related Art

To ensure that DIMM slots of a motherboard work normally, performance of the DIMM slot should be tested. In testing, an electronic load is needed, and must consume different electrical loads (e.g., power consumed) for the motherboard.

A typical electronic load includes a simulation load, an adjusting circuit, and a voltage dividing circuit. The simulation load can be a metal-oxide-semiconductor field-effect transistor (MOSFET). The adjusting circuit adjusts a sample voltage from the voltage dividing circuit to change a voltage of a gate of the MOSFET. Thus, a conduction rate of the MOSFET is changed correspondingly such that the electronic load can supply different load currents, thereby correspondingly consuming different electrical loads for the motherboard. However, the adjusting circuit usually includes a sliding rheostat, and the sample voltage of the voltage dividing circuit is changed via adjusting a position of a sliding terminal of the sliding rheostat manually, which is inconvenient.

Therefore, there is room for improvement within the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views. Wherever possible, the same reference numbers are used throughout the drawings to refer to the same or like elements of an embodiment.

FIG. 1 is a block diagram of an electronic load, according to an exemplary embodiment, and showing the electronic load connected to a DIMM slot.

FIG. 2 is a partial circuit diagram of the electronic load shown in FIG. 1.

FIG. 3 is a circuit diagram of a comparison circuit of the electronic load shown in FIG. 1.

### DETAILED DESCRIPTION

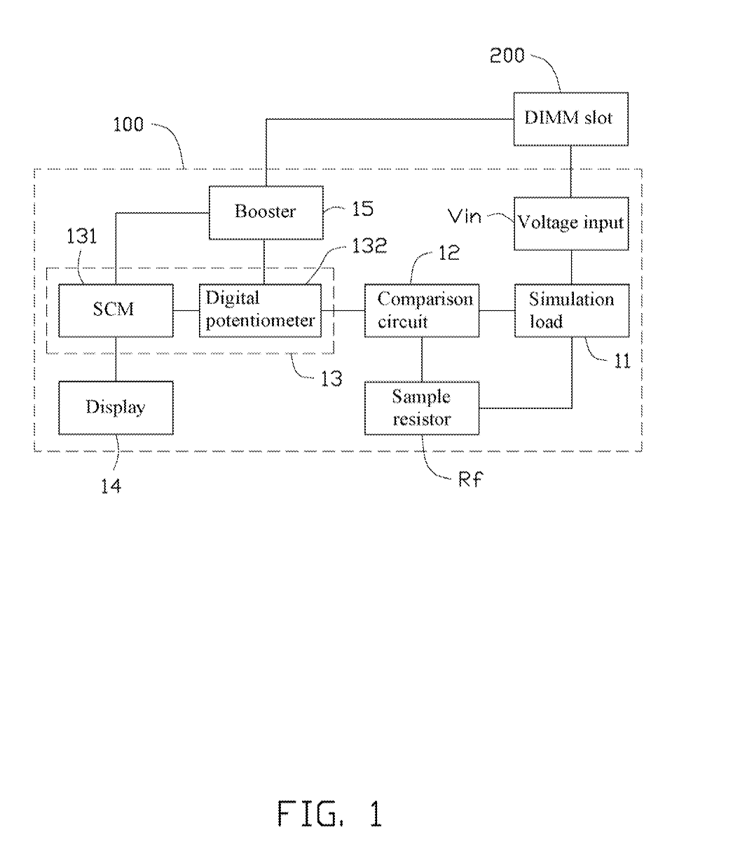

FIG. 1 is a block diagram of an electronic load 100, according to an exemplary embodiment. The electronic load 100 is connected to a DIMM slot 200, and configured for simulating different electrical loads for the DIMM slot 200 when the DIMM slot 200 is under test. The electronic load 100 includes a voltage input Vin, a simulation load 11, a sample resistor Rf, a comparison circuit 12, and a voltage control circuit 13.

The voltage input Vin is connected to a power pin (not shown) of the DIMM slot 200, and used to supply power to the electronic load 100.

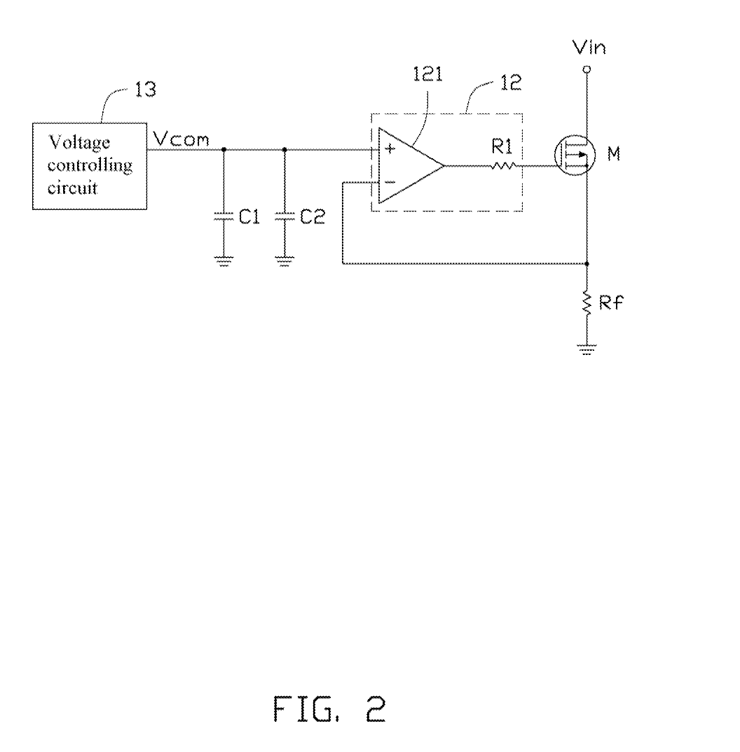

FIG. 2 shows the simulation load 11 in one embodiment. The simulation load 11 is a metal-oxide-semiconductor field-effect transistor (MOSFET) M. A source of the MOSFET M is connected to ground through the sample resistor Rf. A gate of the MOSFET M is connected to the comparison circuit 12. A drain of the MOSFET M is connected to the voltage input Vin, and consumes the different electrical loads for the DIMM slot 200 via the voltage input Vin.

The comparison circuit 12 includes a comparator 121 and a resistor R1. A positive input of the comparator 121 is connected to the voltage control circuit 13, and receives a control voltage Vcom from the voltage control circuit 13. A negative input of the comparator 121 is connected to the source of the MOSFET M. An output of the comparator 121 is connected to the gate of the MOSFET M through the resistor R1.

The positive input of the comparator 121 is also connected to ground through at least a capacitor for filtering the control voltage Vcom output to the positive input of the comparator 121. In this embodiment, the positive input of the comparator 121 is connected to ground through two capacitors C1, C2 which are connected in parallel.

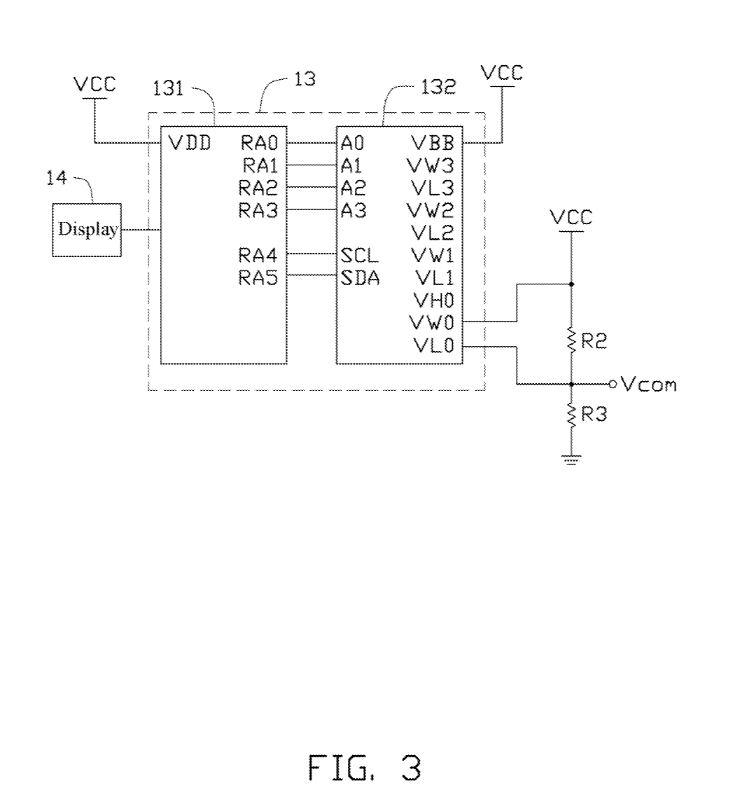

FIG. 3 shows the voltage control circuit 13 according to one embodiment. The voltage control circuit 13 includes a single chip microcomputer (SCM) 131 and a digital potentiometer 132. The SCM 131 includes a power pin VDD and a group of control pins RA0-RA5. The power pin VDD is connected to a power supply VCC. The group of the control pins RA0-RA5 are all connected to the digital potentiometer 132, and control the digital potentiometer 132 to output the control voltage Vcom.

In one embodiment, the digital potentiometer 132 can be an X9241 digital potentiometer. The digital potentiometer 132 includes a power terminal VBB, a group of address pins A0-A3, a serial clock pin SCL, a serial data pin SDA, a group of sliding pins VW0-VW3, a group of low pins VL0-VL3, and a group of high pins VH0-VH3. The power terminal VBB is connected to the power supply VCC. The group of the address pins A0-A3, the serial clock pin SCL, and the serial data pin SDA are connected to the corresponding control pins RA0-RA5. A sliding pin VW0 is connected to the power supply VCC, and also connected to the ground through two resistors R2, R3 which are connected in series. A low pin VL0 is connected between the resistors R2, R3, and also connected to the positive input of the comparator 121 to output the control voltage Vcom. The group of the sliding pin VW1-VW3, the low pins VL1-VL3, and the high pins VH0-VH3 are all idle.

In use, when the DIMM slot 200 is tested, according to performance of the digital potentiometer 132, an adjustable resistor (not shown) is connected between the sliding pin VW0 and the low pin VL0. A first terminal of the adjustable resistor is connected between the power supply VCC and the resistor R2. A second terminal of the adjustable resistor is connected between the resistors R2, R3. Thus, under the control of the SCM 131, the digital potentiometer 132 can change the resistance of the adjustable resistor, and the control voltage Vcom that the low pin VL0 outputs to the comparator 121 is changed correspondingly.

The sample resistor Rf samples current flowing through the MOSFET M, and outputs the sampled current to the negative input of the comparator 121. According to performance of the comparator 121, when a voltage of the positive input of the comparator 121 equals to a voltage of the negative input of the comparator 121, a steady voltage is output by the comparator 121 to drive the MOSFET M turn on. In detail, a voltage V1 of the negative input of the comparator 121 can be calculated according to the following formula (1):

V1=R_{L}*I (1)

where the parameter R_{L} is a resistance of the sample resistor Rf, and the parameter I is current flowing though the MOSFET M.

Due to the connection of the voltage control circuit 13, the voltage V2 of the positive input of the comparator 121 can be calculated according to the following formula (2):

V2=Vcom (2)

According to the above formulas (1) and (2), the parameter Vcom can be calculated according to the following formula (3):

Vcom=R_{L}*I (3)

Thus, when the control voltage Vcom is changed under the control of the SCM 131, the current flowing through the MOSFET M (i.e., simulation load 11) is adjusted correspondingly, and thereby the load power the electronic load 100 consumed for the DIMM slot 200 through the voltage input Vin being adjustable.

In other embodiments, the electronic load 100 further includes a display 14. The display 14 is connected to the SCM 131, and configured for display a voltage value of the voltage input Vin, current value flowing through the simulation load 11, and a load power the simulation load 11 consumed.

The power supply VCC can be an external power source, and can also be integrated with the voltage from the power pin of the DIMM slot 200. In detail, the electronic load 100 further includes a booster 15 (e.g., a voltage booster). A first terminal of the booster 15 is connected to the power pin of the DIMM slot 200. A second terminal of the booster 15 is connected to both the SCM 131 and the digital potentiometer 132. The booster 15 boosts the voltage from the power pin of the DIMM slot 200 and outputting the boosted voltage to both the SCM 131 and the digital potentiometer 132.

In the present specification and claims, the word “a” or “an” preceding an element does not exclude the presence of a plurality of such elements. Further, the word “comprising” does not exclude the presence of elements or steps other than those listed.

It is to be also understood that even though numerous characteristics and advantages of exemplary embodiments have been set forth in the foregoing description, together with details of the structures and functions of the embodiments, the disclosure is illustrative only, and changes may be made in detail, especially in matters of arrangement of parts within the principles of this disclosure to the full extent indicated by the broad general meaning of the terms in which the appended claims are expressed.

What is claimed is:

1. An electronic load, comprising:
a simulation load;
a comparison circuit comprising a comparator, an output of the comparator electronically connected to the simulation load;
a sample resistor sampling current flowing through the simulation load, and outputting the sampled current to a negative input of the comparator; and
a voltage control circuit comprising a digital potentiometer; wherein the digital potentiometer outputs an adjustable control voltage to a positive input of the comparator to control the simulation load to output an adjustable current.

2. The electronic load of claim 1, wherein the positive input of the comparator is connected to ground through at least a capacitor for filtering the adjustable control voltage output to the positive input of the comparator.

3. The electronic load of claim 2, wherein the positive input of the comparator is connected to ground through two capacitors which are connected in parallel.

4. The electronic load of claim 1, wherein the simulation load is a metal-oxide-semiconductor field-effect transistor (MOSFET), a source of the MOSFET is connected to ground through the sample resistor, a gate of the MOSFET is connected to the output of the comparison circuit, and a drain of the MOSFET outputs the adjustable current.

5. The electronic load of claim 4, further comprising a voltage input connected to both the drain of the MOSFET and a power pin of a dual inline memory modules (DIMM) slot, the simulation load outputs the adjustable current to the DIMM slot through the voltage input.

6. The electronic load of claim 5, wherein the voltage control circuit further comprises a single chip microcomputer (SCM) connected to the digital potentiometer, and the SCM controls the digital potentiometer output the adjustable control voltage.

7. The electronic load of claim 6, wherein the SCM comprises a group of control pins, the digital potentiometer comprises a group of address pins, a serial clock pin, and a serial data pin, the group of address pins, the serial clock pin, and the serial data pin are respectively connected to the corresponding control pins.

8. The electronic load of claim 6, wherein the digital potentiometer further comprises a group of sliding pins, a group of low pins, and a group of high pins, one of the sliding pins is connected to a power supply, and also connected to ground through a group of resistors which are connected in series, one of the low pins is connected between the group of resistors connected in series, and also connected to the positive input of the comparator to output the adjustable control voltage.

9. The electronic load of claim 8, wherein the SCM further comprises a power pin, the digital potentiometer further comprises a power terminal; both the power pin and the power terminal are connected to the power supply.

10. The electronic load of claim 8, wherein the power supply is an external power source.

11. The electronic load of claim 6, further comprising a booster, one terminal of the booster is connected to the power pin of the DIMM slot, another terminal of the booster is connected to both the SCM and the digital potentiometer, the booster boosts a voltage from the power pin of the DIMM slot, and outputs the boosted voltage to both the SCM and the digital potentiometer.

12. The electronic load of claim 6, further comprising a display connected to the SCM, and used to display a voltage value of the voltage input, current flowing through the simulation load, and a load power the simulation load consumed.

13. An electronic load for simulating different electrical loads for a dual inline memory modules (DIMM) slot, comprising:
a voltage input connected to a power pin of the DIMM slot;
a simulation load connected to the voltage input;
a comparison circuit comprising a comparator, an output of the comparator electronically connected to the simulation load;
a sample resistor sampling current flowing through the simulation load, and outputting the sampled current to a negative input of the comparator; and
a voltage control circuit comprising a digital potentiometer; wherein the digital potentiometer outputs an adjustable control voltage to a positive input of the comparator, and the simulation load outputs an corresponding adjustable current to the DIMM slot through the voltage input.
